(19) United States
(12) Patent Application Publication
(10) Pub. No.: US 2014/0353006 A1
(43) Pub. Date: Dec. 4, 2014

(54) MULTILAYER CIRCUIT BOARD AND METHOD FOR MANUFACTURING SAME

(71) Applicant: Zhen Ding Technology Co., Ltd., Tayuan (TW)

(72) Inventor: TAEKOO LEE, Qinhuangdao (CN)

(73) Assignee: Zhen Ding Technology Co., Ltd., Tayuan (TW)

(21) Appl. No.: 14/153,059

(22) Filed: Jan. 12, 2014

(30) Foreign Application Priority Data
May 29, 2013 (CN) 2013102043685

(51) Int. Cl. H05K 3/46; H05K 1/18; H05K 1/02

(52) U.S. Cl. CPC H05K 3/4614; H05K 1/0298; H05K 1/186; H05K 1/183
USPC 174/251; 156/182; 156/150; 216/13

(57) ABSTRACT

A multilayer circuit board includes a wiring board, a first adhesive sheet, an electronic device, and a second adhesive sheet. The wiring board includes a first wiring layer and a second wiring layer. The first adhesive sheet is adjacent to the first wiring layer. The first adhesive sheet defines a second receiving hole. The second receiving hole and the first receiving hole cooperatively form a receiving cavity. The first adhesive sheet includes a supporting surface. The electronic device is received in the receiving cavity, and includes two electrodes. The second adhesive sheet is adjacent to the second wiring layer, and includes a bottom surface. The third wiring layer is formed on the supporting surface and contacts with the two electrodes. The fourth wiring layer is formed on the bottom surface.

### BACKGROUND

1. Technical Field

The present disclosure relates to a multilayer circuit board and a method for manufacturing the multilayer circuit board.

2. Description of Related Art

Chip packaging structure may include a packaging substrate and a chip. The packaging substrate is configured to form a connecting pad. A typical packaging substrate includes a dielectric layer, two wiring layers arranged on opposite sides of the dielectric layer and a plurality of conductive vias formed in the dielectric layer, the vias being electrically connected to the two wiring layers. A typical method for forming the conductive vias is a laser etching method. However, if operators use the laser etching method to define the conductive vias, lasers may beat onto the electrodes of electronic devices, to damage the electronic devices. In addition, if lasers are missed, this will cause open circuit, which may reduce the yield rate of the product.

What is needed therefore is a multilayer circuit board and a method for manufacturing the multilayer circuit board that can overcome the above-mentioned problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 shows a schematic, cross-sectional view of a supporting sheet, an adhesive film laminated on the supporting sheet, and a first copper foil laminated on the adhesive film, according to an exemplary embodiment.

FIG. 2 is a schematic, cross-sectional view of the first copper foil in FIG. 1 defining a first through hole, and an electronic device received in the first through hole.

FIG. 3 is a schematic, cross-sectional view of a first adhesive sheet, a wiring board having a through hole, a second adhesive sheet, and a second copper foil.

FIG. 4 is a schematic, cross-sectional view of the first adhesive sheet, the wiring board, the second adhesive sheet, and the second copper foil laminated on the first copper foil of FIG. 2 to form a multilayer substrate.

FIG. 5 is similar to FIG. 4, but showing that the supporting sheet and the adhesive film are removed.

FIG. 6 is a schematic view of a multilayer circuit board, according to an exemplary embodiment of the present disclosure.

### DETAILED DESCRIPTION

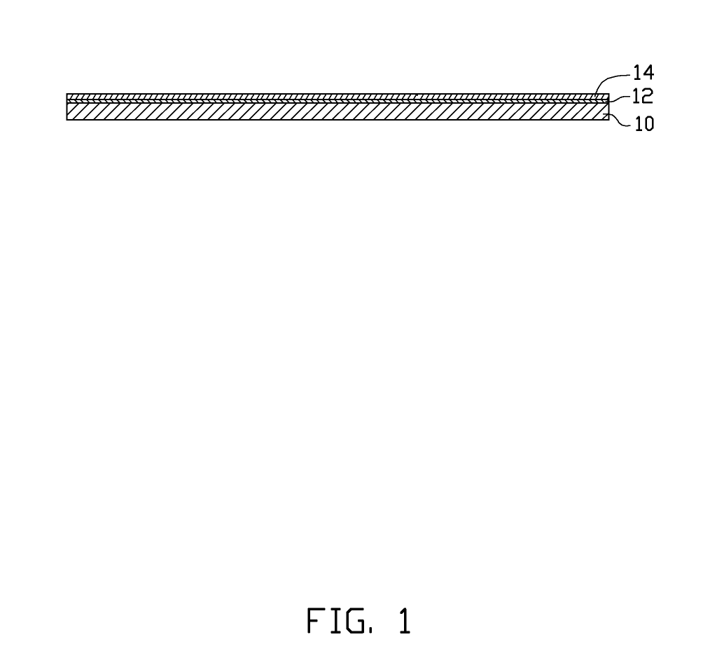

FIGS. 1-6 show a method for manufacturing a multilayer circuit board according to an exemplary embodiment which includes the following steps.

FIG. 1 shows that in step 1, a supporting sheet 10 is provided, together with an adhesive film 12 and a first copper foil 14.

The supporting sheet 10 is configured to support the adhesive film 12 and the first copper foil 14. The supporting sheet 10 is a polyimide (PI) sheet, a glass fiber laminate or a copper sheet. The adhesive film 12 is a double-sided adhesive, which is sandwiched between the supporting sheet 10 and the first copper foil 14, and configured to adhesively connect the first copper foil 14 to the supporting sheet 10. In the embodiment, the adhesive film 12 is comprised of a peelable adhesive, such as a PET release film.

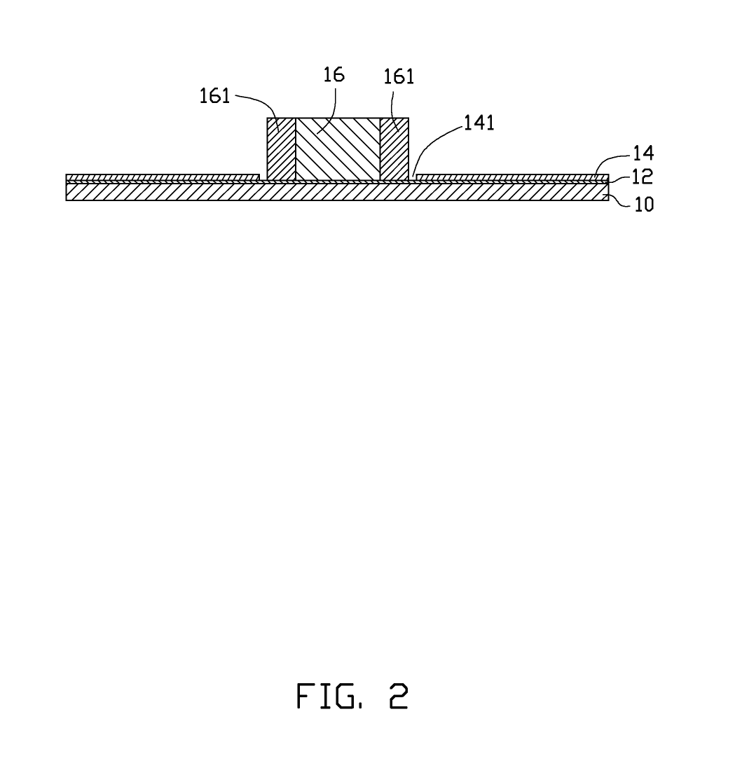

FIG. 2 shows that in step 2, a first through hole 141 is defined in the first copper foil 14, and an electronic device 16 is positioned on the adhesive film 12 through the first through hole 141.

In the embodiment, the first through hole 141 is defined by an etching method. The adhesive film 12 is exposed through the first through hole 141. The first through hole 141 has a shape same as that of the electronic device 16. The first through hole 141 has an area slightly smaller than that of the electronic device 16. The electronic device 16 is a passive element, such as, capacitor, and includes two electrodes 161.

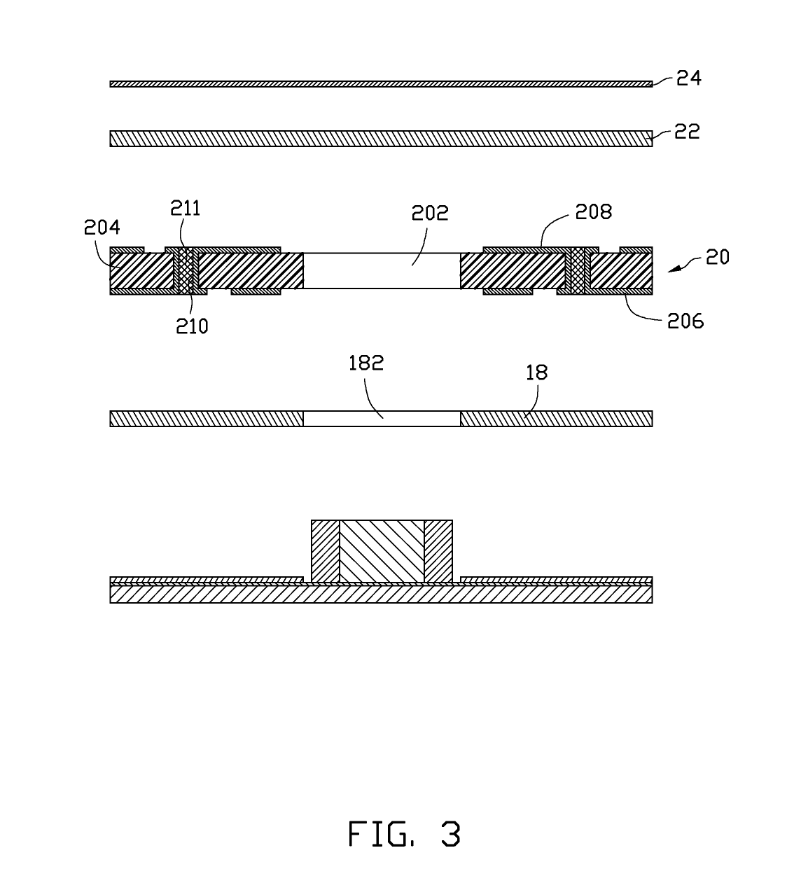

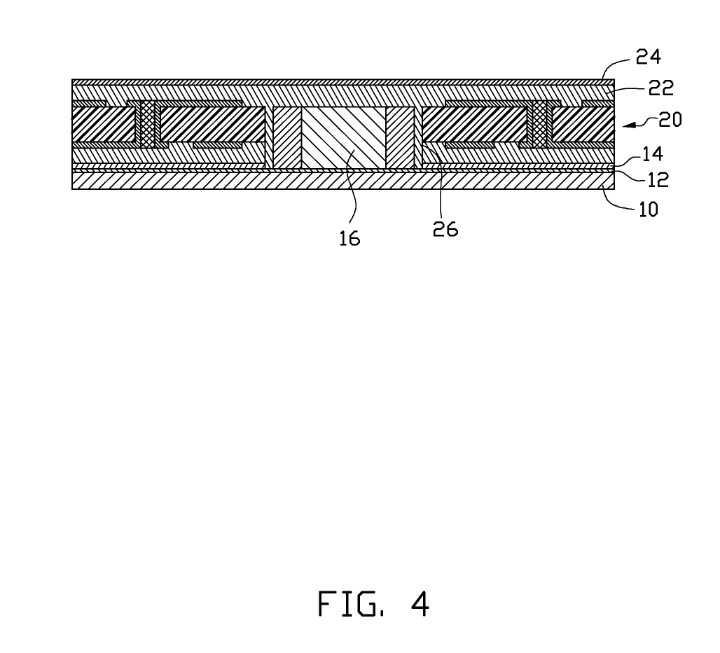

FIGS. 3-4 show that in step 3, a first adhesive sheet 18 is laminated on the first copper foil 14, a wiring board 20 is laminated on the first adhesive sheet 18, a second adhesive sheet 22 is laminated on the wiring board 20, and a second copper foil 24 is laminated on the second adhesive sheet 22.

In the embodiment, the wiring board 20 is a double-sided wiring board, and includes an insulative layer 204, a first wiring layer 206, and a second wiring layer 208. The insulative layer 204 defines a number of through holes 210. The first wiring layer 206 and the second wiring layer 208 are respectively located on two opposite surfaces (not labeled) of the insulative layer 204. The first wiring layer 206 is electrically connected to the second wiring layer 208 through a conductive material 211 received in each through hole 210. The first adhesive sheet 18 defines a second through hole 182 spatially corresponding to the electronic device 16. The wiring board 20 defines a third through hole 202 also spatially corresponding to the electronic device 16. Both the second through hole 182 and the third through hole 202 align with the first through hole 141, as such, the first through hole 141, the second through hole 182, and the third through hole 202 cooperatively form a receiving cavity 26 for receiving the electronic device 16. In the embodiment, a height of the receiving cavity 26 is substantially equal to a height of the electronic device 16. As such, the electronic device 16 is totally received in the receiving cavity 26.

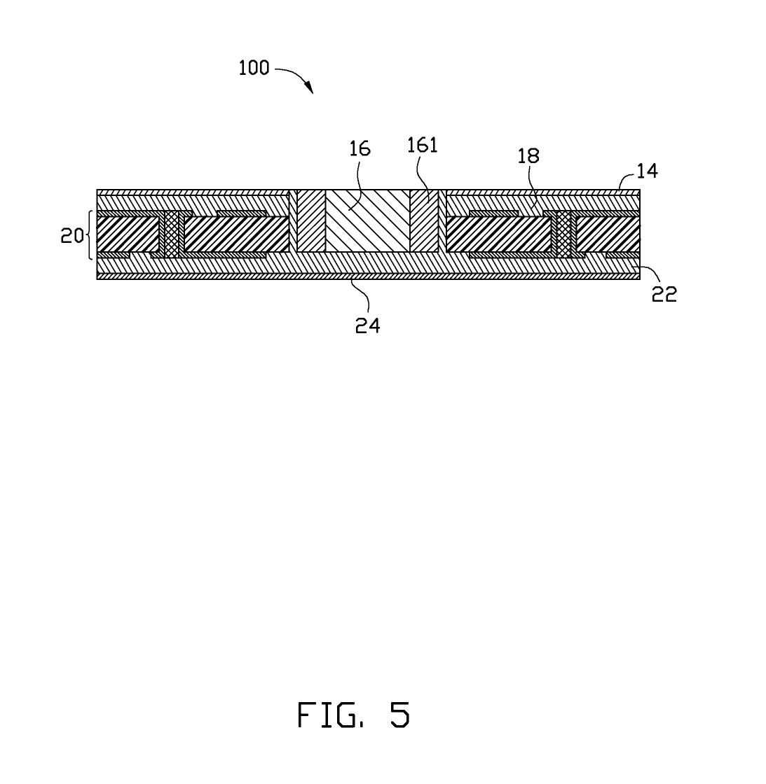

FIG. 5 shows that in step 4, the adhesive film 12 and the supporting sheet 10 are removed to form a multilayer substrate 100. The two electrodes 161 and the first copper foil 14 are exposed.

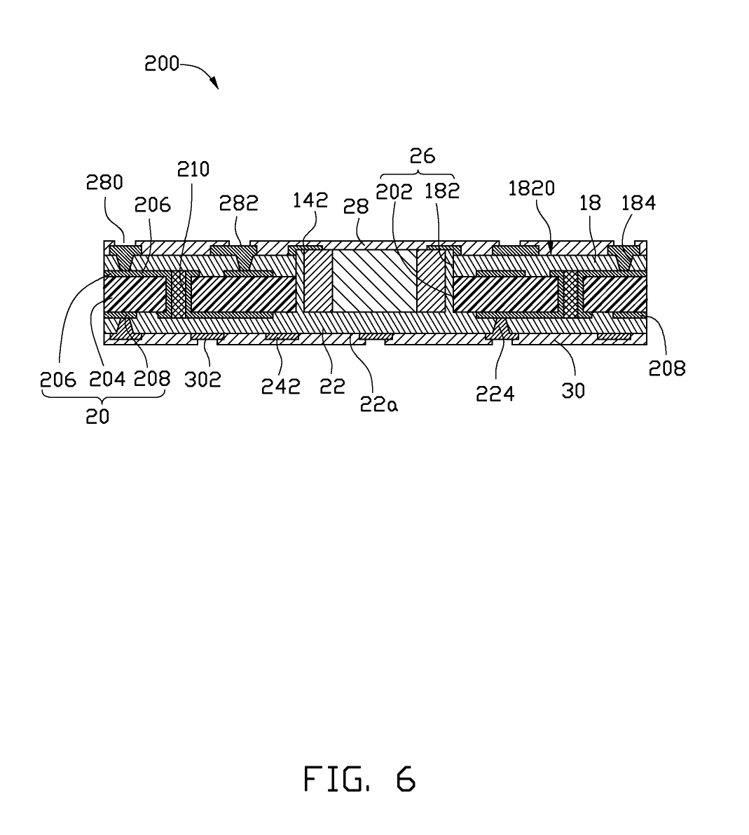

FIG. 6 shows that in step 5, a number of first blind holes 184 are defined in the first adhesive sheet 18, a number of second blind holes 224 are defined in the second adhesive sheet 22, a third wiring layer 142 is formed in the first copper foil 14, a fourth wiring layer 242 is formed in the second wiring layer 24, a first protecting layer 28 is formed on the third wiring layer 142, and a second protecting layer 30 is formed on the fourth wiring layer 242, to form a multilayer wiring board 200.

In the embodiment, the third wiring layer 142 is formed by an electroplating method. In one illustrated embodiment, first, a number of first blind holes 184 are defined penetrating the first adhesive sheet 18 and the first copper foil 14. Inner side surfaces (not labeled) of the first blind holes 184 and the electronic device 16 are coated with seed layers, materials such as copper. The first blind holes 184 are filled with a conductive material through the electroplating method, the electronic device 16 and the first adhesive sheet 18 forms an electroplated copper layer covering the two electrodes 161. Then, a predetermined pattern photo-resist layer is coated on the electroplated copper layer. In addition, the copper layer exposed to the photo-resist layer is removed by an etching solution, as such, forming the third wiring layer 142. Finally, the photo-resist layer is removed.

There is a need to explain, in the electroplating process, the photo-resist layer covering the electroplated copper layer covers the two electrodes 161 and a part of the first adhesive sheet 18, as such, the third wiring layer 142 formed by etching the first cooper foil 14 is electrically connected to the electronic device 16.

The first blind hole 184 and the third wiring layer 142 also can be formed by a patterning method, the patterning method includes following steps: (1) etching a part of first copper foil 14 through a copper etching liquid, to make a thickness of the first copper foil 14 becoming more thin, to form a thin copper layer. In the step, operators can control etching time to control the thickness of the first copper foil 14; (2) the thin copper layer defining a blind hole penetrating the thin copper layer and the first adhesive sheet 18 by an etching method; (3) forming a copper seed layers in an inner sidewall of the blind hole, a surface of the thin copper layer and a surface of a film material received in the receiving cavity 26; (4) coating a photo-resist layer having a predetermined pattern on the copper seed layers, the pre-forming part of the line is exposed from the photo-resist layer, and then forming an electroplating copper layer on the exposed copper seed layer, the thickness of the electroplating copper layer is greater than that of the thin copper layer; (5) removing the photo-resist layer, removing the photo-resist layer covered on the copper seed layer and the thin copper layer, to form the first blind hole 184 and the third wiring layer 142. In the step, operators can control etching time to ensure that the third wiring layer 142 is totally etched.

There is a need to explain, in the electroplating process, the two electrodes 161 or a part of the electrode 161, a film material received in the receiving cavity 26, and a part of the first adhesive sheet 18 are exposed through the photo-resist layer, as such, the first copper foil 14 is electrically connected to the two electrodes 161.

The first blind hole 184 and the third wiring layer 142 also can be formed by a Semi-additive processing method, the method includes following steps: (1) totally etching the first copper foil 14 and removing the first copper foil 14; (2) defining a blind hole penetrating the first adhesive sheet 18 by an etching method; (3) forming a copper seed layers in an inner sidewall of the blind hole, a surface of electronic device 16 and a surface of a film material received in the receiving cavity 26; (4) coating a photo-resist layer having a predetermined pattern on the copper seed layers, the pre-forming part of the line is exposed from the photo-resist layer, and then forming an electroplating copper layer on the exposed copper seed layer; (5) removing the photo-resist layer, removing the photo-resist layer covered on the copper seed layer and the thin copper layer, to form the first blind hole 184 and the third wiring layer 142.

There is a need to explain, the first blind hole 184 and the third wiring layer 142 can be formed by another method, it is not limited to the above three method.

The method for forming the fourth wiring layer 242 is like the same as that of the third wiring layer 142.

The first protecting layer 28 and the second protecting layer 30 can be formed by a printing solder resist ink method. The first protecting layer 28 covers the third wiring layer 142 and a surface of the first adhesive sheet 18 exposed out of the third wiring layer 142. The second protecting layer 30 covers the fourth wiring layer 242 and a surface of the second adhesive sheet 22 exposed out of the fourth wiring layer 242. The first protecting layer 28 and the second protecting layer 30 forming a number of opening area, a surface of the third wiring layer 142 exposed out of the opening area is defined as a first connection pad 282. A surface of the fourth wiring layer 242 exposed out of the opening area is defined as a second connection pad 302.

The multilayer wiring board 200 includes a wiring board 20, a first adhesive sheet 18, a second adhesive sheet 22, a third wiring layer 142, a fourth wiring layer 242, a first protecting layer 28, a second protecting layer 30, and an electronic device 16.

The wiring board 20 is a double-sided wiring board, and an insulative layer 204, a first wiring layer 206, and a second wiring layer 208. The insulative layer 204 defines a number of through holes 210. The first wiring layer 206 and the second wiring layer 208 are respectively located on two opposite surfaces of the insulative layer 204. The first wiring layer 206 is electrically connected to the second wiring layer 208 through a conductive material 211 received in each through hole 210.

The first adhesive sheet 18 is adjacent to the first wiring layer 206. The second adhesive sheet 22 is adjacent to the second wiring layer 208. The first adhesive sheet 18 defines a second through hole 182 and a number of first blind holes 184. The wiring board 20 defines a third through hole 202 spatially corresponding to the second through hole 182. The second through hole 182 and the third through hole 202 cooperatively form a receiving cavity 26.

The electronic device 16 includes two electrodes 161. A height of the electronic device 16 is slightly higher than a height of the receiving cavity 26. The electronic device 16 is received in the receiving cavity 26, with the two electrodes 161 exposed out of the receiving cavity 26.

The third wiring layer 142 is formed on a supporting surface 1820 of the first adhesive sheet 18 facing away from the wiring board 20. The third wiring layer 142 contracts with the two electrodes 161 and electrically connects to the two electrodes 161.

The fourth wiring layer 242 is formed on a bottom surface 22a of the second adhesive sheet 22 facing away from the wiring board 20. In the embodiment, the first wiring layer 206, the second wiring layer 208, the third wiring layer 142, and the fourth wiring board 242 all are made of copper.

The first protecting layer 28 covers the third wiring layer 142. The first protecting layer 28 defines a number of first openings 280. Each first opening 280 aligns with and communicates with a first blind hole 184, and configured for exposing the third wiring layer 142. The exposed third wiring layer 142 is defined as a first connection pad 282.

The second protecting layer 30 covers the fourth wiring layer 242. The second protecting layer 30 defines a number of second openings 30a. Each second opening 30a exposes the fourth wiring layer 242. The exposed fourth wiring layer 242 is defined as a second connection pad 302. The first wiring layer 206 is electrically connected to the third wiring layer 142 through the first connection pad 282. The second wiring layer 208 is electrically connected to the fourth wiring layer 242 through the second connection pad 302.

Unlike conventional multilayer substrates, the electronic device 16 o the multilayer substrate 100 is directly electrically connected to the third wiring layer 142, to reduce a thickness of a non-conductive colloid or dielectric layer, as such, the multilayer substrate 100 become more thin. In addition, a part of the third wiring layer 142 directly electrically connected to the electrodes 161 is formed by the electroplating method, this can prevent open circuit due to lasers being missed, as such, the yield rate of the product is improved. The multilayer substrate 100 also can be used in HDI high density multilayer board.

While certain embodiments have been described and exemplified above, various other embodiments will be apparent from the foregoing disclosure to those skilled in the art. The disclosure is not limited to the particular embodiments described and exemplified but is capable of considerable variation and modification without departure from the scope and spirit of the appended claims.

What is claimed is:

1. A method for manufacturing a multilayer circuit board, comprising:
laminating a supporting sheet, an adhesive film and a first copper foil together in that order, with a first through hole defined in the first copper foil to expose the adhesive film;
positioning an electronic device on the adhesive film through the first through hole, the electronic device comprising two electrodes;
laminating a first adhesive sheet on the first copper foil;
laminating a wiring board on the first adhesive sheet;
laminating a second adhesive sheet on the wiring board;
laminating a second copper foil on the second adhesive sheet, the wiring board comprising an insulative layer, a first wiring layer, and a second wiring layer, the insulative layer defining a plurality of through holes, the first wiring layer and the second wiring layer respectively located on two opposite surfaces of the insulative layer, the first wiring layer electrically connected to the second wiring layer through a conductive material received each through hole, the first adhesive sheet defining a second through hole spatially corresponding to the electronic device, the wiring board defining a third through hole spatially corresponding to the electronic device, the first through hole, the second through hole and the third through hole cooperatively forming a receiving cavity receiving the electronic device, the second adhesive sheet covering the wiring board;
removing the adhesive film and the supporting sheet to form a multilayer substrate;
forming a third wiring layer in the first copper foil, the third wiring layer electrically connecting to the two electrodes; and
forming a fourth wiring layer in the second copper foil.

2. The method of claim 1, comprising:
forming a first protecting layer on the third wiring layer;
forming a second protecting layer on the fourth wiring layer;
defining a plurality of first blind holes in the first adhesive sheet, the first protecting layer defining a plurality of first openings, each first opening aligning with and communicating with a first blind hole and configured for exposing the third wiring layer, the exposed third wiring layer serving as a first connection pad.

3. The method of claim 2, wherein the third wiring layer and the third wiring layer are formed by an electroplating method.

4. The method of claim 3, wherein the electroplating method comprises:
defining a plurality of first blind holes penetrating the first adhesive sheet and the first copper foil;
coating inner side surfaces of the first blind holes and the electronic device with a seed layer;
filling the first blind holes with a conductive material, the electronic device and the first adhesive sheet forming an electroplated copper layer covering the two electrodes;
coating a predetermined pattern photo-resist layer on the electroplated copper layer;
removing the copper layer exposed to the photo-resist layer by an etching solution, so as to form the third wiring layer; and
removing the photo-resist layer.

5. The method of claim 4, wherein the photo-resist layer covering the electroplated copper layer covers the two electrodes and a part of the first adhesive sheet, the third wiring layer is formed by etching the first cooper foil is electrically connected to the electronic device.

6. The method of claim 2, wherein the third wiring layer and the third wiring layer are formed by an patterning method.

7. The method of claim 6, wherein the patterning method comprises:
etching a part of first copper foil through a copper etching liquid, to make a thickness of the first copper foil becoming more thin, to form a thin copper layer;
defining a blind hole penetrating the thin copper layer and the first adhesive sheet in the thin copper layer by an etching method;
forming a copper seed layers in an inner sidewall of the blind hole, a surface of the thin copper layer and a surface of a film material received in the receiving cavity;
coating a photo-resist layer having a predetermined pattern on the copper seed layers, the pre-forming part of the line being exposed from the photo-resist layer, and then forming an electroplating copper layer on the exposed copper seed layer;
removing the photo-resist layer, removing the photo-resist layer covered on the copper seed layer and the thin copper layer, to form the first blind hole and the third wiring layer.

8. The method of claim 2, wherein the third wiring layer and the third wiring layer are formed by a semi-additive processing method.

9. The method of claim 8, wherein the semi-additive processing method comprises:
totally etching the first copper foil and removing the first copper foil;
defining a blind hole penetrating the first adhesive sheet by an etching method;
forming a copper seed layers in an inner sidewall of the blind hole, a surface of electronic device and a surface of a film material received in the receiving cavity;
coating a photo-resist layer having a predetermined pattern on the copper seed layers, the pre-forming part of the line being exposed from the photo-resist layer, and then forming an electroplating copper layer on the exposed copper seed layer;
removing the photo-resist layer, removing the photo-resist layer covered on the copper seed layer and the thin copper layer, to form the first blind hole and the third wiring layer.

10. The method of claim 1, wherein the supporting sheet is a polyimide sheet, a glass fiber laminate or a copper sheet.

11. The method of claim 1, wherein the adhesive film is a double-sided adhesive, which is sandwiched between the supporting sheet and the first copper foil, and configured to adhesively connect the first copper foil to the supporting sheet.

12. The method of claim 1, wherein the adhesive film is comprised of a peelable adhesive.

13. A multilayer circuit board, comprising:
a wiring board comprising an insulative layer, a first wiring layer, and a second wiring layer, the first wiring layer and the second wiring layer respectively located on two opposite surfaces of the insulative layer, the first wiring layer electrically connected to the second wiring layer, the wiring board defining a first receiving hole;
a first adhesive sheet adjacent to the first wiring layer, the first adhesive sheet defining a second receiving hole spatially corresponding to the first receiving hole, the second receiving hole and the first receiving hole cooperatively forming a receiving cavity, the first adhesive sheet comprising a supporting surface facing away from the wiring board;
an electronic device received in the receiving cavity, and comprising two electrodes exposing out of the receiving cavity;
a second adhesive sheet adjacent to the second wiring layer, and comprising a bottom surface facing away from the wiring board;
a third wiring layer formed on the supporting surface, the third wiring layer contacting with the two electrodes and electrically connects to the two electrodes; and
a fourth wiring layer formed on the bottom surface.

14. The multilayer circuit board of claim 13, wherein the insulative layer defines a number of through hole, the first wiring layer is electrically connected to the second wiring layer through a conductive material received in each through hole.

15. The multilayer circuit board of claim 13, comprising a first protecting layer, wherein the first adhesive sheet defines a plurality of first blind holes, the first protecting layer defines a plurality of first openings, each first opening aligns with and communicates with a first blind hole, and configured for exposing the third wiring layer, the exposed third wiring layer serves as a first connection pad.

16. The multilayer circuit board of claim 15, wherein the first wiring layer is electrically connected to the third wiring layer through the first connection pad.

17. The multilayer circuit board of claim 13, comprising a second protecting layer, wherein the second protecting layer covers the fourth wiring layer, the second protecting layer defines a plurality of second openings, each second opening is configured for exposing the fourth wiring layer, the exposed fourth wiring layer serves as a second connection pad.

18. The multilayer circuit board of claim 17, wherein the second wiring layer is electrically connected to the fourth wiring layer through the second connection pad.

19. The multilayer circuit board of claim 14, wherein a height of the electronic device is slightly higher than a height of the receiving cavity, the electronic device is received in the receiving cavity, with the two electrodes exposed out of the receiving cavity.
